(19) United States
(12) Patent Application Publication
(10) Pub. No.: US 2009/0128218 A1
(43) Pub. Date: May 21, 2009

(54) METHOD AND APPARATUS FOR CONTROLLING DEVICE BY DETECTING SCR THEREOF

(75) Inventors: Yisheng Yuan, Shenzhen (CN); Kai Zheng, Shenzhen (CN)

Correspondence Address: KNOBBE MARTENS OLSON & BEAR LLP, 2040 MAIN STREET, FOURTEENTH FLOOR, IRVINE, CA, 92614, US

(73) Assignee: Phoenixtec Power Co., Ltd, Taipei (TW)

(21) Appl. No.: 11/942,959

(22) Filed: Nov. 20, 2007

(51) Int. Cl. H03K 17/687

(52) U.S. Cl. 327/428

(57) ABSTRACT

A method and apparatus for controlling a device by detecting a silicon controlled rectifier (SCR) thereof, as well as a method and apparatus of automatic transfer switch controller thereof are disclosed. In one embodiment, the apparatus includes an input configured to receive input power, an output configured to provide said input power to a load a switch unit electrically coupled between said input and said output, the switch unit having at least one silicon controlled rectifier (SCR), a control unit electrically coupled to the switch unit for detecting the SCR of said switch unit and configured to provide a driving signal, and a device, which is driven by said control unit, wherein the driving signal is determined by the control unit after detecting a voltage value between the gate electrode and the cathode electrode of said SCR.

### BACKGROUND OF THE INVENTION

1. Field of the Invention

The invention relates to a method and apparatus for controlling device by detecting a silicon controlled rectifier (SCR).

2. Description of the Related Technology

Currently, an apparatus for providing multiple current paths between multiple power sources and a load are widely applied, for example, in an uninterrupted power system. The switching element commonly used in the apparatus is a SCR, which is a semi-controlled device, can stably work on the high voltage and high current. However, there are two disadvantages as follows: first, to switch off the SCR is uncontrolled; second, the SCR's maintenance current is very small, generally in the range of two hundred to three hundred milli-amperes when the SCR is conducted, however, its working current is very large, generally in the range of tens to hundreds amperes. It is difficult to detect accurately the maintenance current of SCR in such condition. For example, in the case that two power sources supply the load by two pairs of SCRs, each pair of SCRs conducts current from a single pole of alternating current to a load. When the AC source switches polarity, the first SCR conducts current in the first direction and the second SCR, which is oppositely connected to the first one, conducts current in the second direction. When both SCRs are gated into conduction, both SCRs provide a low resistance path for alternating current power, as current flow alternates back and forth during the AC power cycle. When it comes to transfer to another power source, the transfer from a faulty power source to an alternate power source requires the active or conductive SCRs be de-activated and a second set of SCRs pairs be activated to couple an alternate power source to the load. Such a transfer should be accomplished within a minimum disruption of current flow to the load and also should be accomplished with no current transfer between the two power sources. But, because of the semi-controllable character of the SCR, so that the operation status of the SCR must be accurately estimated before transferring the power sources. U.S. Pat. No. 5,814,904 provides a method for estimating the operation status of the SCR basing on SCRs' characteristics. As shown in FIG. 1, operation principle of the method is based on the fact as follows: according to SCRs' internal characteristics, when a driving current injects in a G electrode, a NPN transistor is conducted, an current I_{C2} is generated to drive a PNP transistor, and the current I_{C2} is amplified into an current I_{C1}. This is a positive feedback. There is a voltage V_{GK}+V_{AG} between AK electrodes when the SCR is conducted, and it can determine the conduction status and the current direction of the SCR basing on the voltage V_{GK}+V_{AG}. However, there are some problems in this method. For instance, in tests of International Rectifier corporation's No. 70tps12pbf SCRs, we detected the voltage between AK electrodes and compared with threshold voltages of −3V, −0.3V, +0.3V and 3V, respectively. And then the conducting statues of the SCR can be estimated. When the SCR is conducted, the voltage between the AK electrodes can be in the range of 0.5 to 4V due to individual difference. Therefore the threshold voltages need to be adjusted accordingly. Additionally, the A electrode and the K electrode of the SCR connect to the power source and the load. There is a voltage disturbance between power source and load, so that when the SCR is switched off, the voltage between the AK electrodes may be in the conducting range of 0.5V to 4V. It may be a mistaken estimation. Accuracy and reliability of the method proposed in prior art are not optimal.

### SUMMARY OF CERTAIN INVENTIVE ASPECTS

One aspect the invention provides a method and apparatus for controlling device by detecting SCR, which can quickly and accurately determine an operation status of a switching unit and control a device.

Another aspect of the invention provides a method and apparatus for controlling device by detecting SCR, comprising: an input configured to receive input power; an output configured to provide said input power to a load; a switching unit electrically coupled between said input and said output, the switch unit having at least one SCR; and a control unit electrically coupled to the switch unit for detecting the SCR of said switch unit and configured to provide a driving signal to drive a device, which is driven by said control unit. The driving signal is determined by the control unit after detecting a voltage value between the gate electrode and the cathode electrode of said SCR.

The control unit may comprise a detect module and a determine module. The detect module is configured to detect the voltage value between the gate electrode and the cathode electrode of the SCR of the switching unit. The determine module is configured to determine an operation status of the switching unit by the voltage value detected by the detect module and provide a driving signal to the device. The driving signal is determined by the operation status of the switching unit.

The determine module may further comprise an analog-to-digital signal conversion of the voltage value detected by the detect module. The threshold value of the signal conversion is a rated voltage between the gate electrode and the cathode electrode of the SCR.

The control unit may be configured to provide a driving signal to a switching element in the device.

Another aspect of the invention provides a method for controlling device by detecting SCR, comprising: detecting the voltage value between the gate electrode and the cathode electrode of a SCR in a switching unit; determining the operation status of the switching unit by the detected voltage value; and providing a driving signal to drive a device, wherein the driving signal is determined by the operation status of the switching unit.

The driving signal may be determined by the operation status of the switching unit which may drive a switch in the device.

The switching unit may include a pair of SCRs in anti-parallel connection.

The driving signal may drive a switch in the device, which is in the same current direction as the switching unit.

Another aspect of the invention provides an automatic transfer switch controller, comprising a first switching unit connected between a first power source and a common output; a second switching unit connected between a second power source and the common output; each of the first and second switching units having at least one SCR. The controller further comprises: a control unit electrically coupled to the first and second switching units, the control unit detecting the SCR of the first switching unit, and then providing driving signal to drive the second switching unit. The driving signal is determined by the control unit after detecting the voltage value between the gate electrode and the cathode electrode of said SCR in the first switching unit and drive the second switching unit, such that transferring to the second power source to supply power to the common output.

The control unit may comprise a detect module configured to detect the voltage value between the gate electrode and the cathode electrode of the SCR in the first switching unit; and a determine module configured to determine an operation status of the first switching unit by said detected voltage value and provide a driving signal to the second switching unit, wherein the driving signal is determined by the operation status of the first switching unit

The determine module may further comprise an analog-to-digital signal conversion of the voltage value detected by the detect module, wherein the threshold voltage value of the analog-to-digital signal conversion is a rated voltage between the gate electrode and the cathode electrode of the SCR.

The switching unit may include a pair of SCRs in anti-parallel connection.

The first power source and the second power source may be two Alternating Current (AC) power sources.

Another aspect of the invention provides method for controlling automatic transfer switch, comprising: detecting the voltage value between the gate electrode and the cathode electrode of a SCR in the first switching unit which connected between the first power source and the common output; determining the operation status of the first switching unit by the detected voltage value; providing a driving signal to drive the second switching unit which connected between the second power source and the common output, wherein the driving signal is determined by the operation status of the first switching unit.

The driving signal may drive a switch in the same current direction as the first switching unit.

An embodiment of the invention is based on positive feedback characteristics of SCRs. For instance, in tests of International Rectifier corporation's No. 70tps12pbf SCRs, the voltages V_{GK} between GK electrodes of the SCRs are in the range of 0.5 to 0.7V, when the silicon controlled rectifiers are conducted, and the voltages V_{GK} are 0V, when the silicon controlled rectifiers are switched off. The individual difference is small.

### BRIEF DESCRIPTION OF THE DRAWINGS

FIG. 1 is a schematic diagram of an SCR.

FIG. 2 is a schematic diagram of an apparatus for controlling device by detecting SCR according to an embodiment of the invention.

FIG. 3 is a schematic diagram of a control unit in an apparatus for controlling device by detecting SCR according to an embodiment of the invention.

FIG. 4 is a schematic diagram of a sample module and determine module in an apparatus for controlling device by detecting SCR according to an embodiment of the invention.

FIG. 5 is a schematic diagram of an automatic transfer switch controller according to an embodiment of the invention.

FIG. 6 is a schematic diagram of a switching unit according to an embodiment of the invention.

### DETAILED DESCRIPTION OF CERTAIN INVENTIVE EMBODIMENTS

Embodiments of the invention will be described with reference to appended drawings.

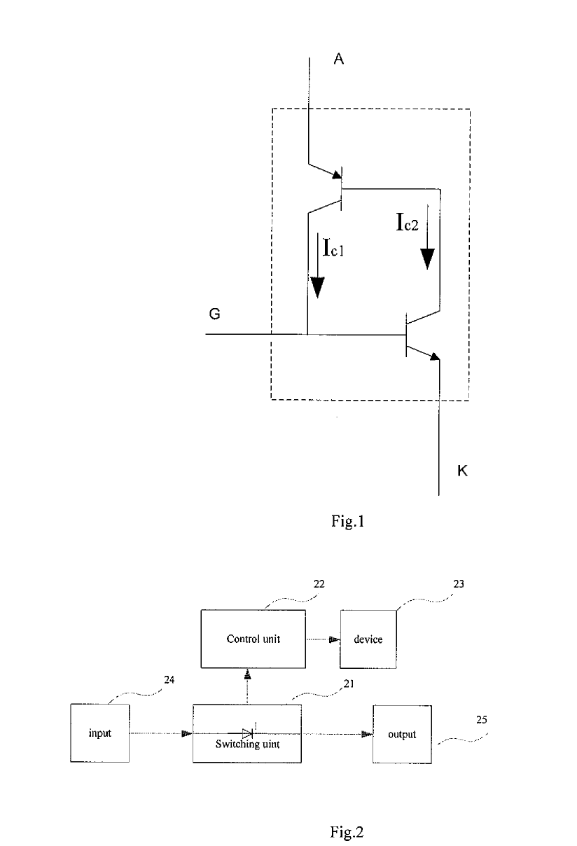

FIG. 1 shows a SCR device. When a driving signal drives the gate electrode (G electrode), a NPN transistor is conducted, a current I_{C2} is generated to drive a PNP transistor, and the current I_{C2} is amplified into a current I_{C1}. This is a positive feedback. There is a voltage V_{GK}+V_{AG} between AK electrodes, when the SCR is conducted. The voltage V_{GK}+V_{AG} can be used to estimate the conduction status and the current direction of the SCR basing on the V_{AK}. This method in the U.S. Pat. No. 5,814,904 of the prior art. For example, in tests of International Rectifier corporation's No. 70tps12pbf SCRs, when the SCR is conducted, the voltage between the AK electrodes can be in the range of 0.5 to 4V, due to individual difference. There may be a mistaken estimation, because there is a voltage disturbance between a power source and a load and the voltage between AK electrodes may be in the conducting range of 0.5V to 4V, when the SCR is switched off. However, a voltage between GK electrodes can be used to determine a current direction according to an embodiment of the invention. Because the voltage V_{GK} between the GK electrodes (the gate electrode and the cathode electrode) is in the range of 0.5 to 0.7V when the SCR is conducted and the voltage V_{GK} is 0V when the SCR is switched off. The voltage V_{GK} can be used as an estimation basis to estimate whether the SCR is conducted (i.e. current direction). The estimation basis according to an embodiment of the invention can ensure that it can avoide the mis-estimation because of the difference of choosing SCRs or the individual difference of SCRs themselves.

An apparatus for controlling device by detecting SCR comprises: an input configured to receive input power; an output configured to provide the input power to a load; a switch unit electrically coupled between the input and the output, the switch unit having at least one SCR; a control unit electrically coupled to the switch unit for detecting the SCR of the switch unit and configured to provide a driving signal to drive a device, which is driven by the control unit. The driving signal is determined by the control unit after detecting a voltage value between the gate electrode and the cathode electrode of the SCR. The control unit comprises a detect module and a determine module. The detect module configured to detect the voltage value between the gate electrode and the cathode electrode of the SCR. The determine module is configured to determine an operation status of the switching unit by the voltage value detected by the detect module and provide the driving signal to the device. The driving signal is determined by the operation status of the switching unit.

FIG. 2 shows a schematic diagram of an apparatus for controlling device by detecting SCR according to another embodiment of the invention. An input 24 is connected with an output 25 by a switching unit 21. The control unit 22 is configured to detect the switching unit 21 and provide a driving signal to drive a device 23.

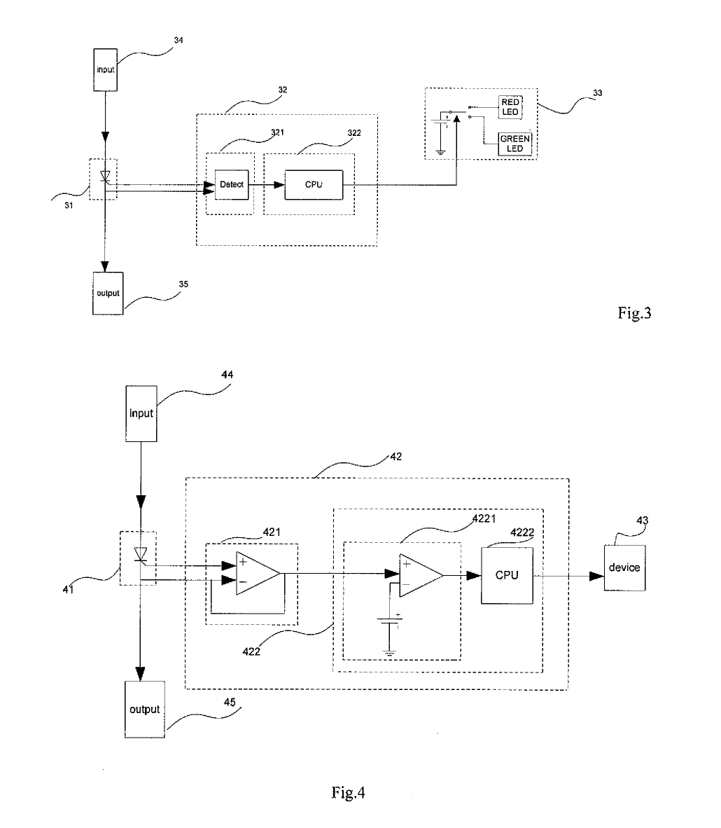

FIG. 3 shows one schematic diagram of the control unit 32 and the device 33 according to another embodiment of the invention. An input 34 is connected with an output 35 by a switching unit 31. The control unit 32 comprises: a detect module 321 and a determine module 322. The detect module 321 configured to detect the voltage value between the gate electrode and the cathode electrode of the SCR in the switching unit 31. The determine module 322 configured to determine an operation status of the switching unit 31 by the voltage value detected by the detect module 321 and provide a driving signal to a device 33. The driving signal is determined by the operation status of the switching unit 31.

FIG. 4 shows another schematic diagram of the control unit according to a certain embodiment of invention. An input 44 is connected with an output 45 by a switching unit 41. The control unit 42 comprises a detect module 421 and a determine module 422. The detect module 421 configured to detect the voltage value between the gate electrode and the cathode electrode of the SCR of the switching unit 41. The determine module 422 configured to determine an operation status of the switching unit 41 by the voltage value detected by the detect module 421 and provide a driving signal to a device 43. The driving signal is determined by the operation status of the switching unit 41. The determine module 422 further comprising: an analog-to-digital signal conversion 4221 of the voltage value detected by the detect module 421. The threshold value of the analog-to-digital signal conversion 4221 is a rated voltage between the gate electrode and the cathode electrode of the SCR of the switching unit 41. The Central Processing Unit (CPU) 4222 receives the digital signal converted by the analog-to-digital signal conversion 4221 and provides a driving signal to a device 43.

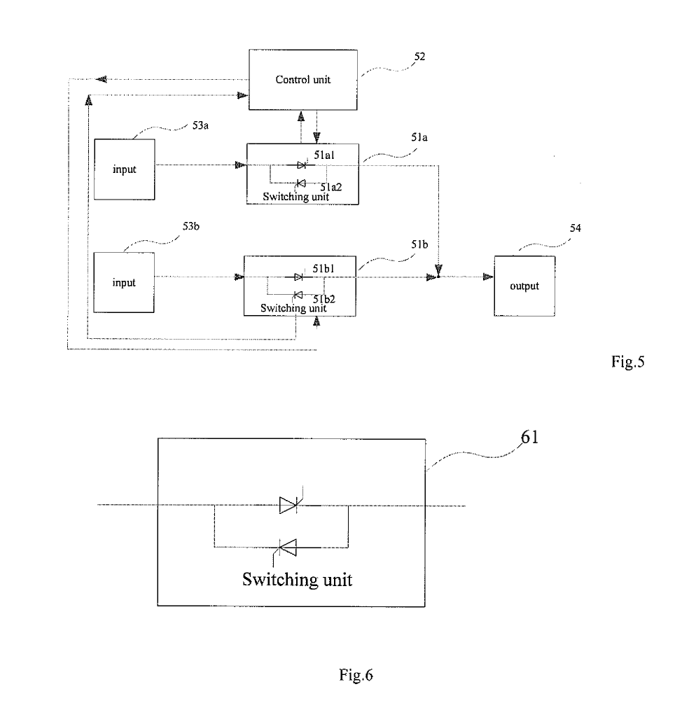

FIG. 5 shows a schematic diagram of an automatic transfer switch controller, in which there are a first power source 53a and a second power source 53b. A first switching unit 51a connected between a first power source 53a and a common output 54. A second switching unit 51b connected between a second power source 53b and the common output 54. Each of the first 51a and second 51b switching units having a SCR. A control unit 52 electrically coupled to the first 51a and second 51b switching units. The control unit 52 detecting the SCR of the first switching unit 51a, and then providing driving signal to drive the second switching unit 51b. The driving signal is determined by the control unit 52 after detecting the voltage value between the gate electrode and the cathode electrode of the SCR in the first switching unit 51a and drive the second switching unit 51b, such that the second power source 53b supply power to the common output 54. The first 51a and the second 51b switching units further comprise a pair of SCRs in anti-parallel connection. As shown in FIG. 6, When determining that the first SCR 51a1 of the first switching unit 51a is conducted, and the second SCR 51a2 of the first switching unit 51a is switched off in the first power source 53a, the control unit 52 provides a driving signal to drive the second switching unit 51b's first SCR 51b1, which is in the same current direction as the first switching unit 51a and the second SCR 51b2 of the second switching unit 51b is switched off. When determining that both of the SCRs 51a1 and 51a2 in the first power source 51a are switched off, the control unit 52 provides a driving signal to drive both of SCRs 51b1 and 51b2 in the second switching unit 51b of the second power source 53b.

FIG. 6 shows a schematic diagram of a pair of SCRs in anti-parallel connection.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An apparatus for controlling a device, the apparatus comprising:
an input configured to receive input power;
an output configured to provide said input power to a load;
a switch unit electrically coupled between said input and said output, the switch unit having at least one silicon controlled rectifier (SCR);
a control unit electrically coupled to the switch unit for detecting the SCR of said switch unit and configured to provide a driving signal; and
a device, which is driven by said control unit,
wherein the driving signal is determined by the control unit after detecting a voltage value between the gate electrode and the cathode electrode of said SCR.

2. The apparatus of claim 1, wherein said control unit comprises:
a detect module configured to detect the voltage value between the gate electrode and the cathode electrode of the SCR;
a determine module configured to determine an operation status of the switching unit by said detected voltage value and provide the driving signal to drive said device, wherein the driving signal is determined by the operation status of said switching unit.

3. The apparatus of claim 2, wherein said determine module further comprises: an analog-to-digital signal conversion of the voltage value detected by the detect module, wherein the threshold value of the analogy-to-digital signal conversion is a rated voltage between the gate electrode and the cathode electrode of the SCR.

4. The apparatus of claim 1, wherein said control unit is configured to provide the driving signal to drive a switch in the device.

5. The apparatus of claim 1, wherein said switching unit includes a pair of SCRs in anti-parallel connection.

6. An automatic transfer switch controller, comprising:
a first switching unit connected between a first power source and a common output;
a second switching unit connected between a second power source and the common output, each of said first and second switching units having a silicon controlled rectifier (SCR); and
a control unit electrically coupled to said first and second switching units, said control unit detecting said SCR of the first switching unit, and then providing a driving signal to drive the second switching unit,
wherein the driving signal is determined by the control unit after detecting the voltage value between the gate electrode and the cathode electrode of said SCR in the first switching unit and drives the second switching unit, such that the second power source supplies power to the common output.

7. The automatic transfer switch controller of claim 6, wherein said control unit comprises:
a detect module configured to detect the voltage value between the gate electrode and the cathode electrode of said SCR; and
a determine module configured to determine the operation status of the first switching unit by said detected voltage value and provide the driving signal to the second switching unit, wherein the driving signal is determined by the operation status of the first switching unit.

8. The automatic transfer switch controller of claim 7, wherein said determine module further comprises:
an analog-to-digital signal conversion of the voltage value detected by the detect module, wherein the threshold value of the analog-to-digital signal conversion is a rated voltage between the gate electrode and the cathode electrode of the SCR.

9. The automatic transfer switch controller of claim 6, wherein said switching unit includes a pair of SCRs in anti-parallel connection.

10. The automatic transfer switch controller of claim 9, wherein the first power source and the second power source are two Alternating Current (AC) power sources.

11. A method for controlling a device comprising:
detecting the voltage value between the gate electrode and the cathode electrode of a silicon controlled rectifier (SCR) in a switching unit;
determining the operation status of the switching unit by the detected voltage value; and
providing a driving signal to drive a device, wherein the driving signal is determined by the operation status of the switching unit.

12. The method of claim 11, wherein said driving signal is used to drive a switch in the device.

13. The method of claim 12 wherein said driving signal is used to drive a switch which is in the same current direction as the switching unit.

14. A method for controlling an automatic transfer switch, comprising:
detecting the voltage value between the gate electrode and the cathode electrode of a silicon controlled rectifier (SCR) in a first switching unit which is connected between a first power source and a common source;
determining the operation status of the first switching unit by the detected voltage value; and
providing a driving signal to drive a second switching unit, wherein the driving signal is determined by the operation status of the first switching unit.

15. The method of claim 14, wherein said driving signal is used to drive a switch in the same current direction as the first switching unit.
